(19) United States
(12) Patent Application Publication
(10) Pub. No.: US 2026/0239633 A1
(43) Pub. Date: Aug. 13, 2026

(54) SEMICONDUCTOR INTEGRATED CIRCUIT

(71) Applicant: ROHM CO., LTD., Kyoto (JP)

(72) Inventor: Tadayuki SAKAMOTO, Kyoto (JP)

(21) Appl. No.: 19/180,737

(22) Filed: Apr. 16, 2025

(30) Foreign Application Priority Data
Apr. 17, 2024 (JP) 2024-066765

(51) Int. Cl. H10D 1/47; H10W 44/00

(52) U.S. Cl. CPC H10D 1/47; H10W 44/401

(57) ABSTRACT

A semiconductor integrated circuit includes a resistor string, which includes: a plurality of polysilicon resistors extending in a first direction, formed to be adjacent in a second direction, and having same dimensions; a plurality of first contact polysilicon regions formed to be in contact with both one end of a (2j-1)th polysilicon resistor and one end of a (2j)th polysilicon resistor where j is a natural number; a plurality of first contact regions formed to overlap with the plurality of first contact polysilicon regions and from which a wiring is drawn out; a plurality of second contact polysilicon regions formed to be in contact with both the other end of the (2j)th polysilicon resistor and the other end of a (2j+1)th polysilicon resistor; and a plurality of second contact regions formed to overlap with the plurality of second contact polysilicon regions and from which a wiring is drawn out.

### CROSS-REFERENCE TO RELATED APPLICATION

The present invention claims priority under 35 U.S.C. § 119 to Japanese Patent Application No. 2024-066765, filed on Apr. 17, 2024, the entire contents of which are incorporated herein by reference.

### TECHNICAL FIELD

The present disclosure relates to a semiconductor integrated circuit.

### BACKGROUND

In response to an increasing demand for energy conservation in recent years, it is required to reduce power consumption in a semiconductor integrated circuit. In order to reduce the power consumption in the semiconductor integrated circuit, it is necessary to increase the impedance of a current path, which requires a resistor element having a high resistance value.

### BRIEF DESCRIPTION OF DRAWINGS

The accompanying drawings, which are incorporated in and constitute a part of the specification, illustrate embodiments of the present disclosure.

FIG. 1 is an equivalent circuit diagram of a semiconductor integrated circuit according to embodiments.

FIG. 2 is a diagram showing a configuration of one resistor element in a comparative technique.

FIG. 3 is a layout diagram of a resistor string according to a comparative technique.

FIG. 4 is a partially enlarged diagram of the resistor string shown in FIG. 3.

FIG. 5 is a layout diagram of a resistor string according to embodiments.

FIG. 6 is a partially enlarged diagram of the resistor string shown in FIG. 5.

FIG. 7 is a layout diagram of a resistor string according to modification 1.

FIG. 8 is a layout diagram of a resistor string according to modification 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Summary of Embodiments

A summary of some exemplary embodiments of the present disclosure will be described. This summary is intended to provide a simplified description of some concepts of one or more embodiments in order to provide a basic understanding of the embodiments as a prelude to the following detailed description, and is not intended to limit the scope of the invention or the disclosure. Furthermore, this summary is not an exhaustive overview of all conceivable embodiments and is not intended to limit essential components of the embodiments. For the sake of convenience, “one embodiment” may be used to refer to one embodiment (example or modification) or multiple embodiments (examples or modifications) disclosed in this specification.

A semiconductor integrated circuit according to embodiments includes a resistor string. The resistor string includes: a plurality of polysilicon resistors extending in a first direction, formed to be adjacent in a second direction, and having same dimensions; a plurality of first contact polysilicon regions formed to be in contact with both one end of a (2j-1)th polysilicon resistor and one end of a (2j)th polysilicon resistor where j is a natural number; a plurality of first contact regions formed to overlap with the plurality of first contact polysilicon regions and from which a wiring is drawn out; a plurality of second contact polysilicon regions formed to be in contact with both the other end of the (2j)th polysilicon resistor and the other end of a (2j+1)th polysilicon resistor; and a plurality of second contact regions formed to overlap with the plurality of second contact polysilicon regions and from which a wiring is drawn out.

According to this configuration, the width of the polysilicon resistor is made smaller than half the width of the contact region, and two adjacent polysilicon resistors are connected to one contact region, thereby reducing the interval between the polysilicon resistors. This makes it possible to reduce the area while realizing a high resistance.

In one embodiment, the polysilicon resistors provided on both outermost sides among the plurality of polysilicon resistors may be dummy resistors. By forming the polysilicon resistors on both of the outermost sides as dummy resistors that are not used in an actual circuit, it is possible to improve a relative precision of the plurality of polysilicon resistors.

A semiconductor integrated circuit according to one embodiment includes a resistor string. The resistor string includes: a plurality of polysilicon resistors having a U-shape, having same dimensions, and arranged side by side in one direction; a plurality of contact polysilicon regions formed to be in contact with both one end of a jth polysilicon resistor and the other end of a (j+1)th polysilicon resistor where j is a natural number; and a plurality of contact regions formed to overlap with the plurality of contact polysilicon regions and from which a wiring is drawn out.

According to this configuration, the width of the polysilicon resistor is made smaller than half the width of the contact region, and two adjacent polysilicon resistors are connected to one contact region, thereby reducing the interval between the polysilicon resistors. This makes it possible to reduce the area while realizing a high resistance.

In one embodiment, the polysilicon resistors provided on both of outermost sides among the plurality of polysilicon resistors may be dummy resistors. By forming the polysilicon resistors on both outermost sides as dummy resistors that are not used in an actual circuit, it is possible to improve the relative precision of the plurality of polysilicon resistors.

### Embodiment

Preferred embodiments will be described below with reference to the drawings. The same or equivalent components, parts, and processes shown in each drawing are designated by the same reference numerals, and duplicate descriptions thereof are omitted as appropriate. Furthermore, the embodiments are not intended to limit the present disclosure, but are merely examples. All of the features and combinations thereof described in the embodiments are not necessarily essential to the present disclosure.

In the present disclosure, “a state where a member A is connected to a member B” includes a case where the member A and the member B are physically directly connected or even a case where the member A and the member B are indirectly connected through any other member that does not affect an electrical connection state between the members A and B or does not impair functions and effects achieved by combinations of the members A and B.

Similarly, “a state where a member C is provided between a member A and a member B” includes a case where the member A and the member C or the member B and the member C are indirectly connected through any other member that does not affect an electrical connection state between the members A and C or the members B and C or does not impair functions and effects achieved by combination of the members A and C or the members B and C, in addition to a case where the member A and the member C or the member B and the member C are directly connected.

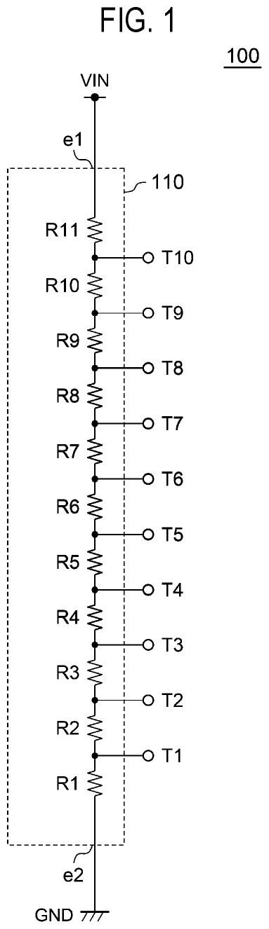

FIG. 1 is an equivalent circuit diagram of a semiconductor integrated circuit 100 according to an embodiment. The semiconductor integrated circuit 100 includes a resistor string 110. The resistor string 110 includes a plurality (n) of resistor elements R1 to Rn connected in series between both ends e1 and e2 thereof. In this example, n=11. The resistor string 110 is provided with a plurality of taps T. For example, the resistor string 110 is used as a resistor voltage divider circuit that divides the voltage between a first end e1 and a second end e2.

For example, the resistor string 110 is used in combination with a selector that selects one of multiple voltages generated at the plurality of taps T1 to T10. Alternatively, in a circuit such as an A/D converter or the like, the multiple voltages generated at the plurality of taps T1 to T10 are used as reference voltages.

Prior to describing the resistor string according to the embodiment, a comparative technique will be described.

### Comparative Technique

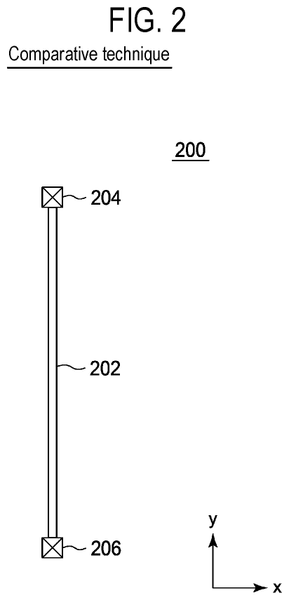

FIG. 2 is a view showing a configuration of one resistor element 200 in a comparative technique. In a typical design, one resistor element 200 is formed as a single configuration unit consisting of a polysilicon resistor 202 extending in a first direction (y-direction in the drawing) and two contact regions 204 and 206 formed on both ends of the polysilicon resistor 202.

Therefore, the resistor string 110 according to the comparative technique is configured as a combination of the resistor elements 200 shown in FIG. 2.

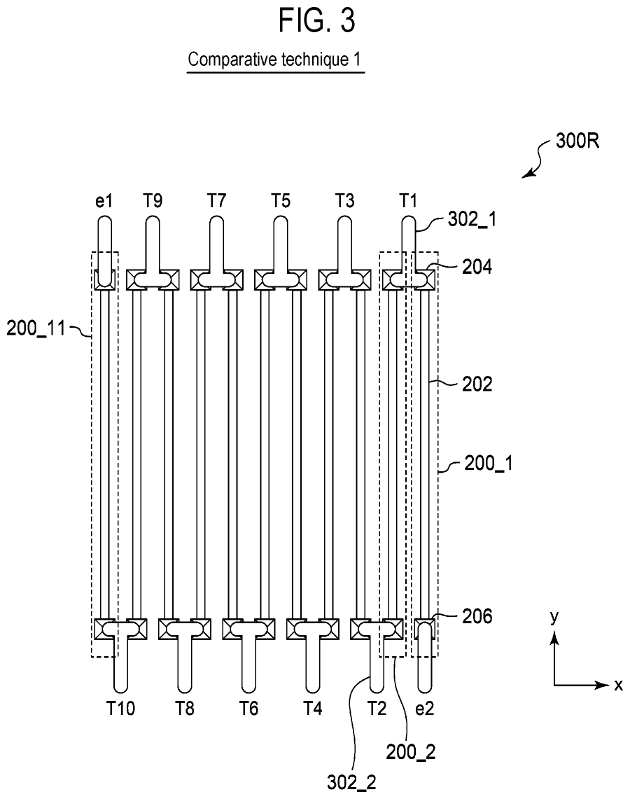

FIG. 3 is a layout diagram of a resistor string 300R according to a comparative technique. The resistor string 300R includes n (n=11) resistor elements 200_1 to 200_n. The n resistor elements 200 are arranged adjacent to each other in a second direction (x-direction in the drawing).

Odd-numbered taps T1, T3, . . . are formed on one end side of the plurality of resistance elements 200. The contact region 204 of each of the (2j−1)th resistance element 200_(2j-1) and the 2jth resistance element 200_2j is connected to a wiring 302_(2j−1) to form a tap T(2j−1) where j is a natural number.

On the other end side of the plurality of resistance elements 200, even-numbered taps T2, T4, . . . are formed. The contact region 206 of each of the 2jth resistance element 200_2j and the (2j+1)th resistance element 200_(2j+1) is connected to a wiring 302_2j to form a tap T2j where j is a natural number.

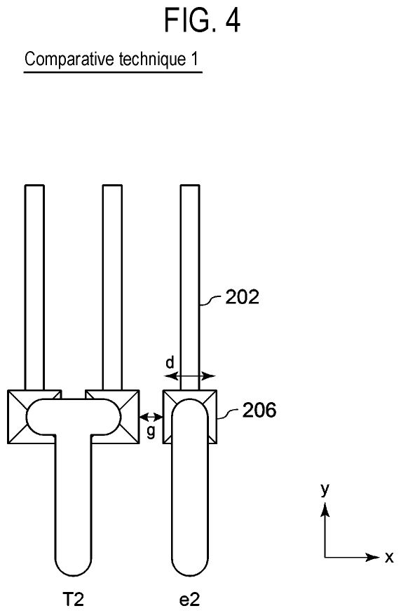

FIG. 4 is a partially enlarged diagram of the resistor string 300R shown in FIG. 3. The minimum size of the contact region 206 in the x-direction is assumed to be d. The minimum interval between adjacent contact regions 206 is assumed to be g. In this case, the minimum value WMIN of the length (width) in the x-direction of the resistor string 300R in FIG. 3 is WMIN=n×d+(n−1)×g. In other words, the size of the resistor string 300R is limited by the size and interval of the contact regions 206, making it difficult to reduce the area of the resistor string 300R.

Next, a resistor string 400 according to an embodiment will be described.

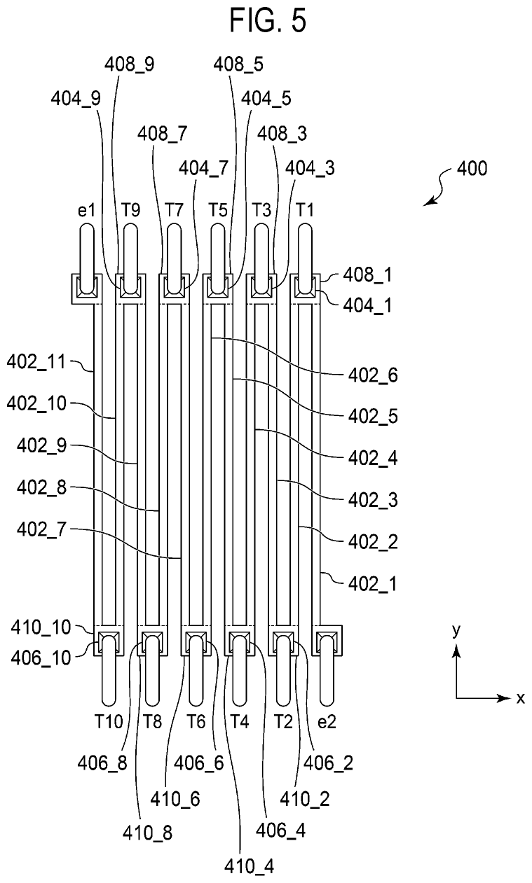

FIG. 5 is a layout diagram of a resistor string 400 according to an embodiment. The resistor string 400 includes a plurality of polysilicon resistors 402, a plurality of first contact regions 404, a plurality of second contact regions 406, a plurality of first contact polysilicon regions 408, and a plurality of second contact polysilicon regions 410.

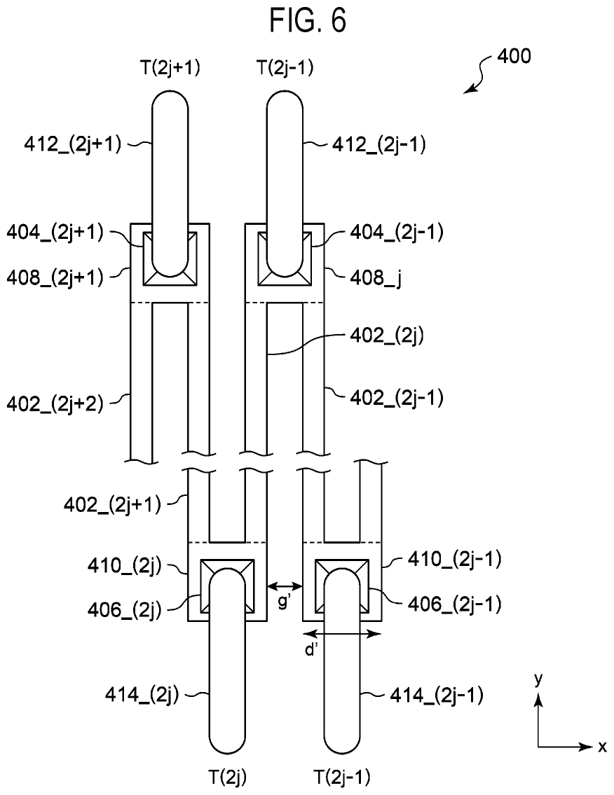

FIG. 6 is a partially enlarged diagram of the resistor string 400 shown in FIG. 5. The polysilicon resistors 402 extend in a first direction (y-direction) and are formed adjacent to each other in a second direction (x-direction). The polysilicon resistors 402 have same dimensions.

The odd-numbered (2j−1)th first contact polysilicon region 408_(2j−1) is formed to be in contact with both one end of the (2j−1)th polysilicon resistor 402_(2j−1) and one end of the (2j)th polysilicon resistor 402_(2j) where j is a natural number.

The odd-numbered (2j−1)th first contact region 404_(2j−1) is formed to overlap with the corresponding first contact polysilicon region 408_(2j−1). In this example, the first contact regions 404 are formed as an inset with respect to the first contact polysilicon regions 408. A wiring as a tap T(2j−1) is drawn out from each first contact region 404_(2j−1).

Further, the even-numbered (2j)th second contact polysilicon region 410_(2j) is formed to be in contact with both of the other end of the even-numbered (2j)th polysilicon resistor 402_(2j) and the other end of the (2j+1)th polysilicon resistor 402_(2j+1) where j is a natural number.

The even-numbered (2j)th second contact region 406_(2j) is formed to overlap with the corresponding second contact polysilicon region 410_(2j). In this example, the second contact regions 406 are formed as an inset with respect to the second contact polysilicon regions 410. A wiring serving as a tap T(2j) is drawn out from each second contact region 406_(2j).

The above is the configuration of the resistor string 400. Next, the advantages of this configuration will be described.

The minimum size in the x-direction of the contact polysilicon regions 408 and 410 is assumed to be d′. The minimum interval between the adjacent contact polysilicon regions 408 and 410 is assumed to be g′.

When k is an integer satisfying n=2k−1, the minimum value W'MIN of the length (width) in the x-direction of the resistor string 400 in FIG. 5 is approximately W'MIN [symbol] k×d′+k×g′.

The comparative technique (FIGS. 3 and 4) and the embodiment (FIGS. 5 and 6) are compared. It is assumed that d′ [symbol] d, g′ [symbol] g, and k [symbol] n/2. Thus, W'MIN [symbol] WMIN×½. In other words, according to the embodiment, the area of the resistor string 400 can be reduced to about ½ compared to the comparative technique.

Next, modifications of the resistor string 400 will be described.

### Modification 1

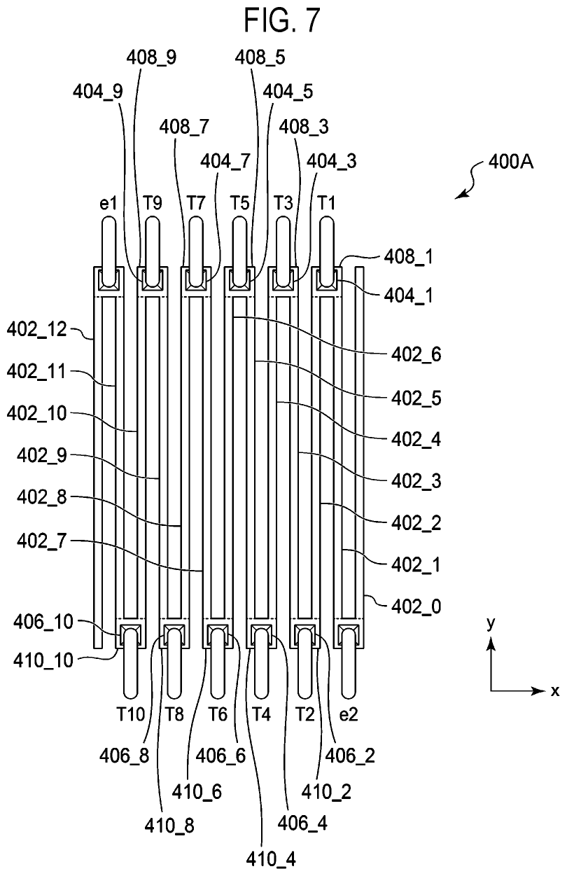

FIG. 7 is a layout diagram of a resistor string 400A according to modification 1. The resistor string 400A includes polysilicon resistors 402_0 and 402_(n+1), which serve as dummy resistors, at both ends thereof. One end of each of the dummy resistors is open, and does not affect the resistance value of the resistor string 400A.

By providing the dummy resistors on both outermost sides, the width of the resistor string 400A is slightly greater than the resistor string 400 shown in FIG. 5, but the relative precision of the plurality of polysilicon resistors is improved as a tradeoff thereof.

### Modification 2

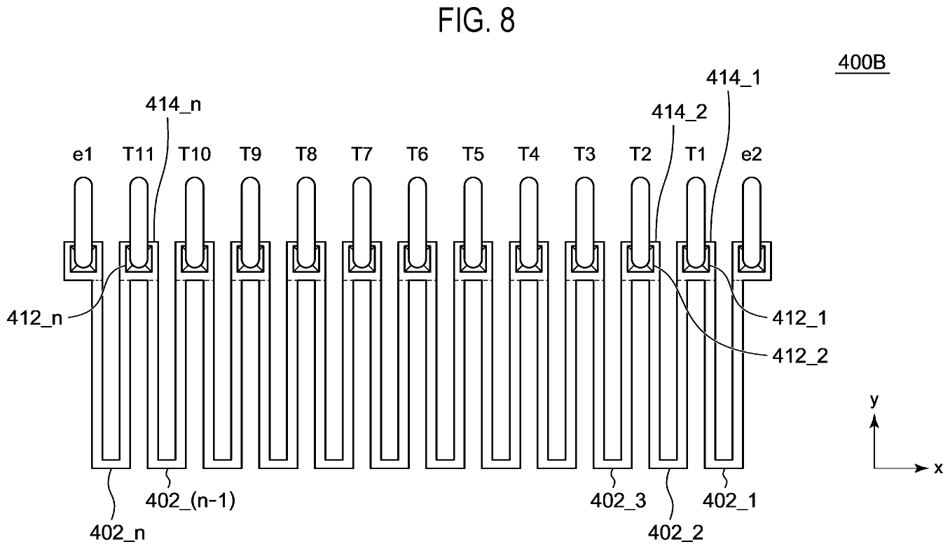

FIG. 8 is a layout diagram of a resistor string 400B according to modification 2. In this modification, the polysilicon resistors 402_1 to 402_n have a U-shape (a U-shape with 90-degree corners) and have same dimensions.

The jth contact polysilicon region 414_j is formed to be in contact with both one end of the jth polysilicon resistor 402_j and the other end of the (j+1)th polysilicon resistor 402_(j+1) where j is a natural number.

The j-th contact region 412_j is formed to overlap with the corresponding contact polysilicon region 414_j. A wiring serving as a tap Tj is drawn out from the j-th contact region 412_j.

According to modification 2, the width in the x-direction is approximately twice as large as that of the resistor string 400 shown in FIG. 3, but the length in the y-direction is approximately half that of the resistor string 400 shown in FIG. 3. Therefore, the area remains almost the same. In modification 2, the taps can be formed along the same side.

In modification 2, dummy resistors may be added to both ends in the same manner as in modification 1. This makes it possible to further improve the relative precision of the polysilicon resistor 402.

The embodiments described using specific terms merely illustrate the principles and applications of the present disclosure. Many modifications and changes in arrangement may be made to the embodiments without departing from the spirit of the present disclosure defined in the claims.

### Supplementary Notes

In one aspect, the technique disclosed in this specification may be grasped as follows.

### Supplementary Note 1

A semiconductor integrated circuit, comprising:
a resistor string,
wherein the resistor string includes:
a plurality of polysilicon resistors extending in a first direction, formed to be adjacent in a second direction, and having same dimensions;
a plurality of first contact polysilicon regions formed to be in contact with both one end of a (2j−1)th polysilicon resistor and one end of a (2j)th polysilicon resistor where j is a natural number;
a plurality of first contact regions formed to overlap with the plurality of first contact polysilicon regions and from which a wiring is drawn out;
a plurality of second contact polysilicon regions formed to be in contact with both the other end of the (2j)th polysilicon resistor and the other end of a (2j+1)th polysilicon resistor; and
a plurality of second contact regions formed to overlap with the plurality of second contact polysilicon regions and from which a wiring is drawn out

### Supplementary Note 2

The semiconductor integrated circuit of Supplementary Note 1, wherein the polysilicon resistors provided on both outermost sides among the plurality of polysilicon resistors are dummy resistors.

### Supplementary Note 3

A semiconductor integrated circuit, comprising:
a resistor string,
wherein the resistor string includes:
   a plurality of polysilicon resistors having a U-shape, having same dimensions, and arranged side by side in one direction;
   a plurality of contact polysilicon regions formed to be in contact with both one end of a jth polysilicon resistor and the other end of a (j+1)th polysilicon resistor where j is a natural number; and
   a plurality of contact regions formed to overlap with the plurality of contact polysilicon regions and from which a wiring is drawn out.

### Supplementary Note 4

The semiconductor integrated circuit of Supplementary Note 3, wherein the polysilicon resistors provided on both outermost sides among the plurality of polysilicon resistors are dummy resistors.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit, comprising:
a resistor string,
wherein the resistor string includes:
a plurality of polysilicon resistors extending in a first direction, formed to be adjacent in a second direction, and having same dimensions;
a plurality of first contact polysilicon regions formed to be in contact with both one end of a (2j−1)th polysilicon resistor and one end of a (2j)th polysilicon resistor where j is a natural number;
a plurality of first contact regions formed to overlap with the plurality of first contact polysilicon regions and from which a wiring is drawn out;
a plurality of second contact polysilicon regions formed to be in contact with both the other end of the (2j)th polysilicon resistor and the other end of a (2j+1)th polysilicon resistor; and
a plurality of second contact regions formed to overlap with the plurality of second contact polysilicon regions and from which a wiring is drawn out.

2. The semiconductor integrated circuit of claim 1, wherein the polysilicon resistors provided on both outermost sides among the plurality of polysilicon resistors are dummy resistors.

3. A semiconductor integrated circuit, comprising:
a resistor string,
wherein the resistor string includes:
a plurality of polysilicon resistors each having a U-shape, having same dimensions, and arranged side by side in one direction;
a plurality of contact polysilicon regions formed to be in contact with both one end of a jth polysilicon resistor and the other end of a (j+1)th polysilicon resistor where j is a natural number; and
a plurality of contact regions formed to overlap with the plurality of contact polysilicon regions and from which a wiring is drawn out.

4. The semiconductor integrated circuit of claim 3, wherein the polysilicon resistors provided on both outermost sides among the plurality of polysilicon resistors are dummy resistors.
